(19) United States
(12) Patent Application Publication
(10) Pub. No.: US 2013/0120936 A1
(43) Pub. Date: May 16, 2013

(54) SCANNER PROTECTION CASING AND SYSTEM OF READING THE HEIGHT OF THE PELLET BED OF GRID CARS INSIDE A GRID FURNACE COMPRISING A SCANNER PROTECTED BY SAID CASING

(71) Applicant: VALE S/A, Rio de Janeiro (BR)

(72) Inventors: Eduardo Frigini DE JESUS, Vitoria (BR); Flavio Silva NICOLETTI, Serra (BR)

(73) Assignee: VALE S/A, Rio de Janeiro (BR)

(21) Appl. No.: 13/674,746

(22) Filed: Nov. 12, 2012

Related U.S. Application Data
(60) Provisional application No. 61/558,893, filed on Nov. 11, 2011.

(51) Int. Cl. H05K 7/20

(52) U.S. Cl. CPC H05K 7/20218
USPC 361/699

(57) ABSTRACT

A scanner protection casing including an external cabinet, an internal cabinet within which a scanner is positioned, a thermal insulation material between the external cabinet and the internal cabinet that reduces the thermal conductivity between the external cabinet and the internal cabinet. Further, the internal cabinet has a first side wall and a second side wall and the space between the first side wall and a second side wall is filled with a cooling fluid.

### CROSS-REFERENCE TO RELATED APPLICATION

This application claims priority to U.S. Provisional Patent Appl. No. 61/558,893 filed Nov. 11, 2011. This prior application is hereby incorporated by reference herein in its entirety.

### FIELD OF INVENTION

Aspects of the present invention relate to a casing that allows for a scanner installed therein to read the height of the pellet bed of grid cars inside the grid furnace.

### SUMMARY OF THE INVENTION

According to various aspects of the current invention, a casing or cabinet may be provided to allow for a scanner to read a pellet bed in a grid car inside a grid furnace, and generally including equipment able to be utilized in aggressive environments if the equipment is installed inside the casing. A system according to various aspects may include a control module configured to monitor and control the conditions inside the casing. The casing may allow for the scanner located therein to be in an environment having a controlled temperature and humidity. The casing may be tightly sealed to prevent any dust, humidity and/or gases that could damage the scanner operation from getting in contact with the scanner.

According to various aspects, the casing may have safety devices to ensure scanner integrity even under adverse conditions. A module may be integrated into the casing monitoring to control operation of the scanner.

According to various aspects, the scanner protection casing of this invention comprises

an external cabinet;

an internal cabinet within which a scanner is positioned;

between the external cabinet and the internal cabinet there is a thermal insulation material reducing the thermal conductivity between the external cabinet and the internal cabinet;

the internal cabinet having a first side wall and a second side wall, the space between the first side wall and a second side wall being filled with a cooling fluid.

Also, in various aspects of the current invention, a passage may be provided on the second stainless plate wherein a laser beam may pass.

According to various aspects, a system of reading the height of the pellet bed of grid cars inside a grid furnace comprising a scanner protected by the above-discussed scanner protection casing may be provided.

### BRIEF DESCRIPTION OF THE FIGURES

FIG. 1 illustrates a casing in an isometric perspective, according to various aspects of the current invention;

FIG. 2 illustrates a frontal view of the casing in a partial cross-section, according to various aspects;

FIG. 3 illustrates a side view of the casing in a cross section, according to various aspects; and

FIG. 4 illustrates the casing put on top of the furnace, according to various aspects.

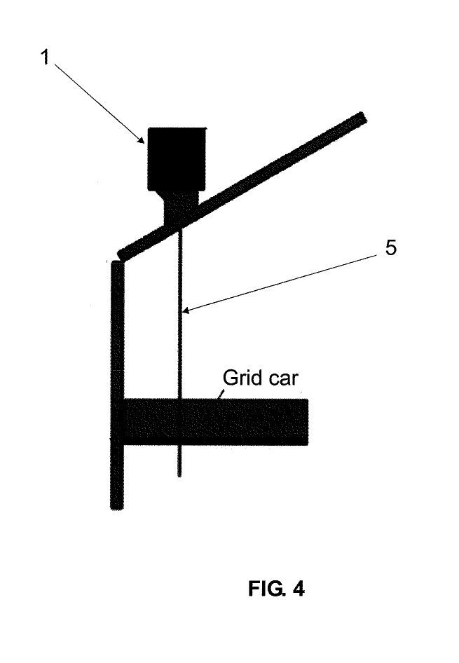

### DETAILED DESCRIPTION OF THE INVENTION

Various aspects of the current invention allow for the protection of a scanner located inside a grid furnace where the external temperature may be above 50 degrees Celsius and the internal temperature of a furnace may be above 250 degrees Celsius. Inside and outside environments of the furnace may also have iron ore particles in suspension. Various aspects of the casing may be used in a plurality of types of equipment that requires a scanner to operate in aggressive environments such as environments having a large amount of dust and/or high temperatures that are capable of damaging the scanner.

According to various aspects, the casing may have a plurality of components such as, for example, glass, water gallery, expansion valve, insulation cap, cooling cap, conduit, and the like. Aspects of this invention may include several elements for the control of the internal environment of the casing.

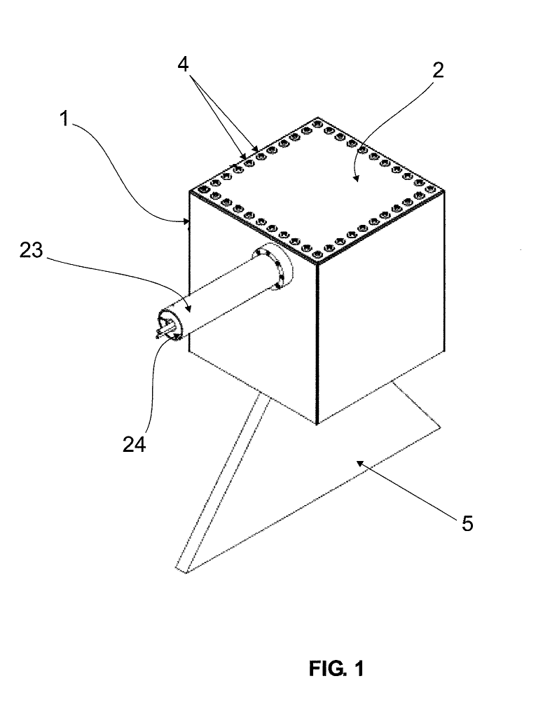

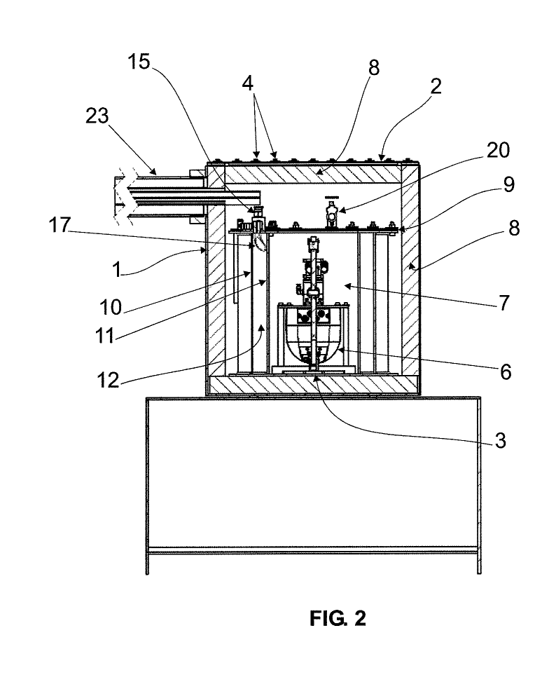

The scanner protection refrigerated casing in accordance with this invention is illustrated in FIGS. 1 through 3. The casing may have an external cabinet 1 with a cap 2 fixed by the screws 4, and an opening 3 where the signal 5 of the scanner 6 is emitted from the cabinet.

According to various aspects, an internal cabinet 7 is located inside the external cabinet 1. Between the external cabinet 1 and the internal cabinet 7, there is a thermal insulation material 8 that reduces the thermal conductivity between the external cabinet 1 and the internal cabinet 7. The thermal insulation material can be rock wool or any other insulation material that can reduces thermal conductivity.

The internal cabinet 7 may have a cap 9 fixed by screws and the scanner 6 is installed inside the internal cabinet 7. The internal cabinet 7 may have a first side wall 10 and a second side wall 11, the space between the two walls 10 and 11 being filled with a cooling fluid 12 that may be water. According to various aspects, during normal operation conditions there may not be any cooling fluid 12 circulating between the walls 10 and 11 of the internal cabinet 7.

According to various aspects, a coil (not shown) surrounds the internal cabinet 7 between walls 10 and 11, this coil is immersed in the cooling fluid 12. A cooling gas under pressure and in the liquid state coming from a commercial condensation module goes through an expansion valve 14 and gets into the coil, the coil exchanges the heat of the cooling gases with the cooling fluid 12.

A temperature sensor 15 installed in the internal cabinet 7 monitors the temperature of the cooling fluid 12 inside walls 10 and 11. The cooling fluid 12 is responsible for keeping the temperature of the internal cabinet 7 in levels that are previously selected with a control module.

According to various aspects, in case of lack of cooling gas for removal of the heat of the cooling fluid 12, a conduit may allow for the cooling fluid 12 to circulate around the internal cabinet 7, the cooling fluid 12 gets inside through a first connection 17 and gets out through a second connection (not shown) removing the heat from the internal cabinet 7.

The interior part of the internal cabinet 7 may be tightly sealed, and after the installation of the scanner 6 a vacuum may be created inside the internal cabinet 7 in order to remove any humidity. Optionally, the scanner 6 may be inserted in the cabinet 7 with a humid gas that is not prejudicial to the scanner operation.

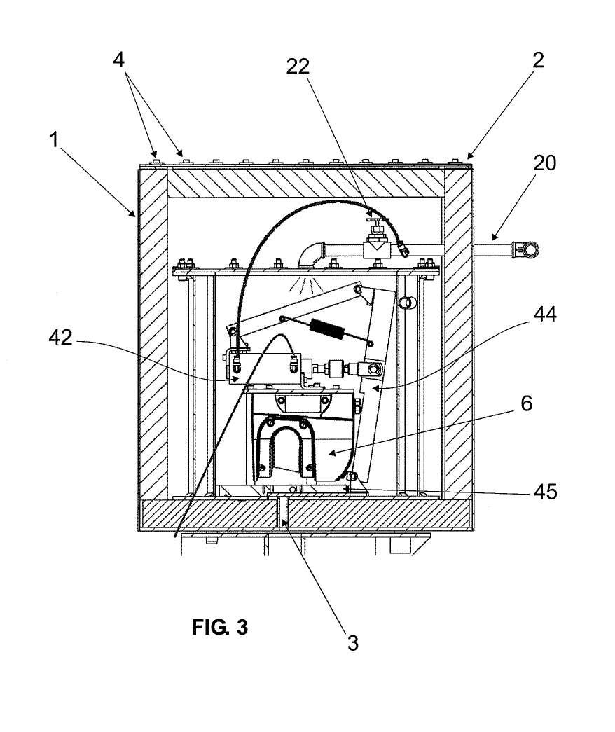

As illustrated by FIG. 3, a pipe 20 inflates compressed air inside the internal cabinet 7 in order to keep a constant pressure inside de cabinet 7, avoiding heat and dust of going inside the cabinet 7. The pipe 20 has a valve 22 that controls the air outputted inside the cabinet 7. Before this valve 22 there is a small air outlet which leads compressed air into the piston 42. The compressed air pushes on the piston 42 that drives a lever 44 that opens a hatch 45 under the scanner 6.

According to various aspects, a tube 23 with thermal insulation 24 protects all wires and piping coming in and out of the casing.

1. A scanner protection casing, comprising:
an external cabinet;
an internal cabinet within which a scanner is positioned;
a thermal insulation material between the external cabinet and the internal cabinet wherein the thermal insulation material reduces the thermal conductivity between the external cabinet and the internal cabinet;
the internal cabinet having a first side wall and a second side wall; and
a cooling fluid within a space between the first side wall and a second side wall.

2. The scanner protection casing, according to claim 1, wherein the thermal insulation material positioned between the external cabinet and the internal cabinet is rock wool.

3. The scanner protection casing, according to claim 1, wherein the cooling fluid within the space between the first side wall and a second side wall of the internal cabinet is water.

4. The scanner protection casing, according to claim 1, further comprising a pipe configured to provide compressed air inside the internal cabinet to keep a constant pressure inside the internal cabinet.

5. A system of reading a height of a pellet bed of grid cars inside a grid furnace comprising a scanner protected by the scanner protection casing as defined in claim 1.
